(19) United States
(12) Patent Application Publication
(10) Pub. No.: US 2026/0038606 A1
(43) Pub. Date: Feb. 5, 2026

(54) ERROR HANDLING AVOIDANCE

(71) Applicant: Micron Technology, Inc., Boise, ID (US)

(72) Inventors: Ugo Russo, Boise, ID (US); Yingda Dong, Los Altos, CA (US); Ching-Huang Lu, Fremont, CA (US); Thomas Lentz, Boise, ID (US)

(21) Appl. No.: 19/269,730

(22) Filed: Jul. 15, 2025

Related U.S. Application Data
(60) Provisional application No. 63/677,877, filed on Jul. 31, 2024.

(51) Int. Cl. G11C 16/34; G11C 16/26; G11C 29/02

(52) U.S. Cl. CPC G11C 16/3404; G11C 16/26; G11C 29/028

(57) ABSTRACT

An example method includes tracking, via a controller external to a memory device comprising a plurality groups of memory cells, respective read offset categories for the plurality of groups of memory cells. The method can include: in response to receiving a read request targeting a group of memory cells of the plurality of groups of memory cells, determining a current read offset category corresponding to the group of memory cells; selecting, based at least on the determined current read offset category, one of multiple read types to execute to read the group of memory cells; and executing the selected one of the multiple read types to read the group of memory cells.

### PRIORITY INFORMATION

This application claims the benefit of U.S. Provisional Application No. 63/677,877, filed Jul. 31, 2024, the contents of which are incorporated herein by reference.

### TECHNICAL FIELD

Embodiments of the disclosure relate generally to memory systems, and more specifically, relate to apparatuses and methods for error handling avoidance in memory systems.

### BACKGROUND

A memory system can be a storage device, a memory module, or a hybrid of a storage device and a memory module. Examples of a storage device include a solid-state drive (SSD), a Universal Flash Storage (UFS) drive, a secure digital (SD) card, an embedded Multiple Media Card (eMMC), and a hard disk drive (HDD). Examples of memory modules include a dual in-line memory module (DIMM) and various types of non-volatile dual in-line memory modules (NVDIMMs). Memory systems include one or more memory components (e.g., memory devices) that store data. The memory components can be, for example, non-volatile memory components (e.g., NAND flash memory devices) and volatile memory components (e.g., DRAM devices). In general, a host system can utilize a memory system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example computing system having a memory system for performing error handling avoidance in accordance with various embodiments of the present disclosure.

FIG. 2A illustrates example threshold voltage distributions associated with memory cells to be read in accordance with various embodiments of the present disclosure.

FIG. 2B illustrates an example of the temporal voltage shift that can be caused by slow charge loss exhibited by memory cells that can be read in accordance with various embodiments of the present disclosure.

FIG. 3 depicts an example graph illustrating the relationship between memory cell threshold voltage and slow charge loss time as well as a number of read offset categories (e.g., “bins”) that can be used in association with error handling avoidance in accordance with various embodiments of the present disclosure.

FIG. 4A illustrates an example read type selection component associated with error handling avoidance in accordance with various embodiments of the present disclosure.

FIG. 4B illustrates example tables that can be used in association with error handling avoidance in accordance with various embodiments of the present disclosure.

FIG. 5 is a graph illustrating BER over time associated with a number of read types that can be performed in association with error handling avoidance in accordance with various embodiments of the present disclosure.

FIG. 6 is a graph illustrating BER over time (e.g., SCL time) for multiple different read types that are selectable, based on a determined current read offset category (e.g., bin), to perform a read operation in association with error handling avoidance in accordance with various embodiments of the present disclosure.

FIG. 7 is a flow diagram that illustrates an example method for error handling avoidance in accordance with various embodiments of the present disclosure.

### DETAILED DESCRIPTION

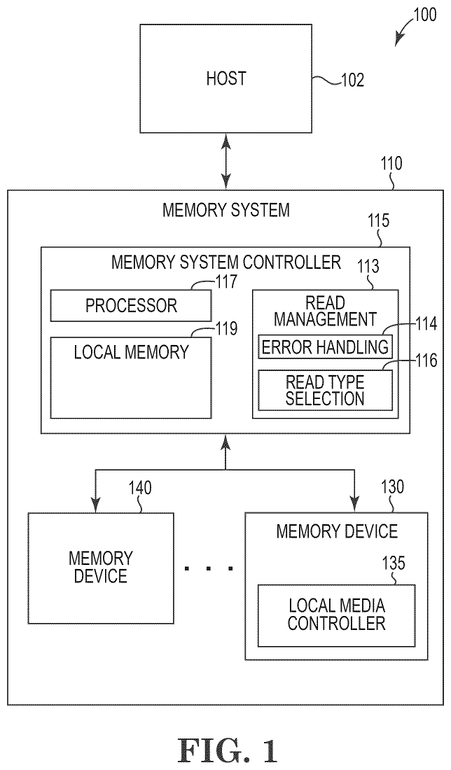

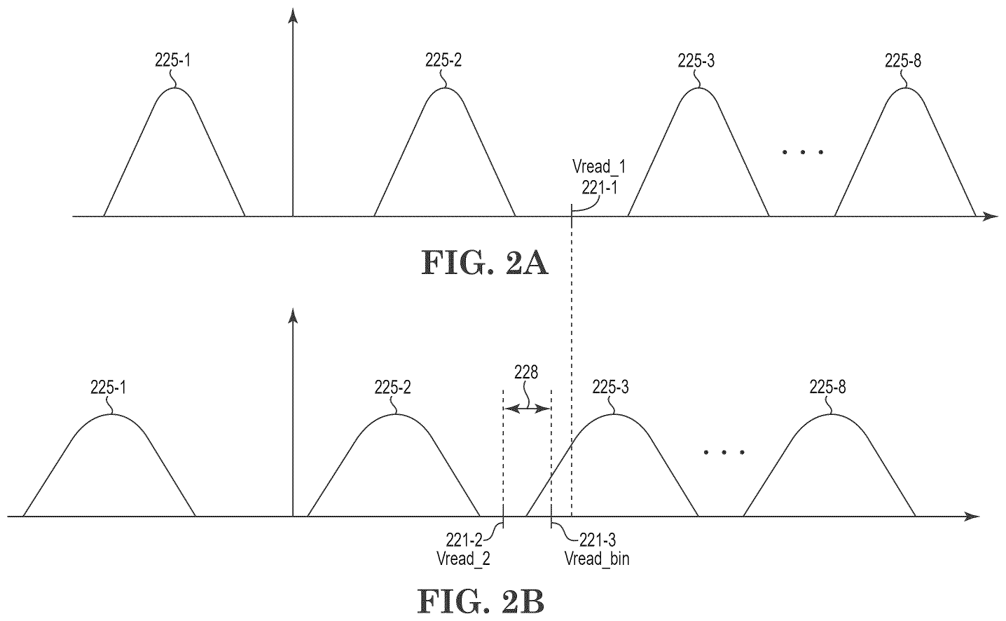

Aspects of the present disclosure are directed to apparatuses and methods for error handling avoidance within memory systems, such as storage systems comprising NAND flash memory devices. NAND flash memory includes an array of many memory cells that can be arranged in row and column fashion and grouped in physical blocks. The cells can include a charge storage node such as a floating gate or charge-trap layer which allows the cells to be programmed to store one or more bits by adjusting the charge stored on the storage node. As described further in FIG. 1 and FIG. 2, such cells can be programmed to multiple different threshold voltage (Vt) levels, which provides Vt distributions corresponding to different respective data states (e.g., logical values). Accordingly, a cell programmable to 2ⁿ different Vt levels can store “n” bits. For example, a cell programmable to eight different states (e.g., n=3) can store three bits data, with each state being encoded with a different three-bit pattern (e.g., 000, 010, 111, etc.). A sensing operation (e.g., a read or a program verify operation) involves determining the current data state of the cell by comparing the current Vt of the cell to one or more reference voltages (e.g., read voltages) to identify the current Vt distribution to which the cell belongs. The ability to distinguish between adjacent data states can become more difficult with scaling (e.g., due to reduced read window budget margin). For instance, as the quantity of Vt distributions increases for a given read window, which may only be a few Volts, the distance between adjacent Vt distributions decreases.

The Vt distributions of programmed cells can shift and/or widen due to various factors, which leads to increased bit error rates associated with reads. As an example, a phenomenon referred to as slow charge loss (SCL) causes the Vt of a programmed cell to shift (e.g., downward) over time. The amount of shift can be more rapid very shortly after the cell is programmed and then can slow (e.g., in a generally logarithmic manner) as the time after programming increases (e.g., by minutes, hours, days, years). In general, SCL leads to increased BER over time as read margins narrow. Failure to account for SCL in association with reading cells leads to increased BERs, which can lead to an increased rate of the memory system entering a “read error handling” procedure as a result of failing to decode data responsive to a particular read command (e.g., a host read command). Such read error handling procedures are often more time consuming and/or resource intensive, which adversely affects system quality of service (QoS). The rate at which a memory system enters a read error handling procedure can be referred to as the “trigger rate” and is often used as a critical metric for memory systems. Error recovery operations associated with read error handling can include various read re-try procedures and/or redundant array of independent NAND (RAIN) recovery, for example.

Various memory systems employ error detection/correction schemes such as error correction code (ECC) schemes that involve encoding data programmed to a group of cells (e.g., a page) and which are capable of correcting up to a threshold number of errors in a page of data being read responsive to a host read command. Such memory systems can avoid entering read error handling unless/until the system (e.g., the ECC engine) is unable to decode the data (e.g., the number of erroneous bits in the read data exceeds the threshold number correctable based on the strength of the ECC), which can be referred to as an uncorrectable ECC error (UECC).

Various different types of read operations can be used to achieve a particular BER designed to avoid error handling (e.g., to maintain or reduce the trigger rate). However, such different types of read operations also have different corresponding read performance (e.g., read latency and/or resource usage), which impacts system performance regardless of whether error handling is invoked. For instance, some read operations can utilize a single set of read trims, while others may utilize a number of different sets of read trims (e.g., read offset voltages). Some read operations can be associated with soft decoding (e.g., 1H1S, 1H2S, etc.) such as may be implemented by a low-density parity check (LDPC) decoder. Some read operations can involve sweeping a number of read voltages around a baseline read voltage in order to more accurately find the read voltage corresponding to the bottom of the “valley” between states. Such a read can be referred to as a “valley tracking” read operation, which involves a relatively high read time and a relatively low BER. Various read operations can also adjust the precharge time (e.g., of the bit lines), which affects the BER corresponding to the read (e.g., faster precharge leads to higher BER). It can be beneficial to employ different read types at different times in order to achieve a desired trigger rate. However, since the read performance corresponding to different read types affects system performance, it can be desirable to determine when to select which particular read type to use in order to achieve a particular read error handling trigger rate while also preventing undue read performance degradation. As one example, always utilizing a valley tracking read (e.g., a calibrated read) may provide a lowest achievable BER. However, unnecessary read performance reduction can be avoided by selectively using a different (e.g., faster) read type if such read type can achieve an acceptable BER (e.g., a BER sufficiently low so as to avoid invoking read error handling).

Some prior approaches to reducing the read error handling trigger rate can include utilizing a read operation that involves tracking the SCL associated with programmed cells. For example, in some instances, the time after programming (TAP) corresponding to groups of cells (e.g., pages, groups of pages, blocks, etc.) can be tracked directly via timer circuitry. In some instances, a background scan can be performed (e.g., by the system controller) to track the amount of Vt shift associated with a particular Vt distribution, with the determined amount of shift serving as a proxy for the TAP and/or SCL time. The groups of cells (e.g., a word line, a word line group, etc.) being tracked can be placed in “bins” corresponding to the different determined amounts of SCL, with the different bins having different respective read offset voltages used for reads. Such prior methods that account SCL can reduce the BER as compared to methods that do not track SCL. However, as described further below, such prior methods often have residual read position loss (RPL) since the read trims used for the different “bins” are not located exactly between adjacent Vt distributions (e.g., at a center/bottom of the “valley” between adjacent states). Additionally, as SCL time increases, the read window budget decreases, which, in combination with RPL, leads to increased BER over time. Therefore, it can be beneficial to provide a read method that involves tracking SCL and determining when to selectively apply different read types in order to improve (e.g., decrease) error handling trigger rate.

Various embodiments of the present disclosure address the above and other deficiencies by providing apparatuses and methods that can improve memory system performance. As described further herein, various embodiments involve tracking respective read offset categories for a plurality of groups of memory cells and, in response to receiving a read request targeting a group of memory cells of the plurality of groups of memory cells: determining a current read offset category corresponding to the group of memory cells; and selecting, based at least on the determined current read offset category, one of multiple read types to execute to read the group of memory cells. The group of memory cells can then be read using the selected one of the multiple read types.

FIG. 1 illustrates an example computing system 100 having a memory system 110 for error handling avoidance in accordance with various embodiments of the present disclosure. The memory system 110 includes a system controller 115 and media in the form of a number of memory devices, which can be one or more non-volatile memory devices (e.g., 130), one or more volatile memory devices (e.g., 140), or a combination of such.

The memory system 110 can be a storage system, a memory module, or a hybrid of a storage system and a memory module, for example. Example storage systems can include, but are not limited to, a solid-state drive (SSD), or a managed NAND (MNAND) drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM). In general, the computing environment shown in FIG. 1 can include a host system 102 (e.g., a host system) that is coupled to one or more memory system 110, which can be of a same or different type. As used herein, “coupled to” generally refers to a connection between components, which can be an indirect communicative connection or direct communicative connection (e.g., without intervening components), whether wired or wireless, including connections such as electrical, optical, magnetic, etc. The host 102 can use the memory system 110 by writing data to and reading data from the memory system 110.

The host 102 can be a computing device such as a desktop computer, laptop computer, network server, mobile device, vehicle (e.g., airplane, drone, vehicle, or other conveyance), Internet of Things (IoT) enabled device, or other such computing device that includes a memory and a processing device (e.g., a processor). The host 102 can, for example, include a processor chipset and a software stack executable thereby. The host 102 can be coupled to the memory system 110 via a physical host interface (not shown in FIG. 1) that can provide an interface for passing control, address, data, and other signals between the memory system 110 and the host 102. Examples of a physical host interface include, but are not limited to, a serial advanced technology attachment (SATA) interface, a peripheral component interconnect express (PCIe) interface, a universal flash storage (UFS) interface, a universal serial bus (USB) interface, Fibre Channel, Serial Attached SCSI (SAS), etc. The physical host interface can be used to transmit data between the host 102 and the memory system 110. The host 102 can further utilize an NVM Express (NVMe) interface, for example, to access the memory devices 130 when the memory system 110 is coupled with the host 102 by the PCIe interface.

The memory devices can include various combinations of the different types of non-volatile memory devices 130 and/or volatile memory devices 140. The volatile memory devices (e.g., memory device 140) can be, but are not limited to, random access memory (RAM), such as dynamic random access memory (DRAM) and synchronous dynamic random access memory (SDRAM). In some embodiments, the memory devices 130, 140 include local media controllers (e.g., local media controller 135) that operate in conjunction with memory system controller 115 to execute operations on one or more memory cells of the memory devices 130, 140.

An example of non-volatile memory devices (e.g., memory device 130) includes a NAND flash memory device. Each of the memory devices 130 can include one or more arrays of memory cells. The memory cells can include single level cells (SLCs) that can store one bit per cell, multi-level cells (MLCs) that can store two bits per cell, triple level cells (TLCs) that can store three bits per cell, quad-level cells (QLCs) that can store four bits per cell, and/or penta-level cells (PLCs) that can store five bits per cell, among others. NAND arrays can have a two-dimensional (2D) or three-dimensional (3D) architecture.

Although non-volatile memory components such as NAND type flash memory are described, the memory device 130 can be based on various other types of non-volatile memory such as read-only memory (ROM), phase change memory (PCM), magnetoresistive random access memory (MRAM), NOR flash memory, electrically erasable programmable read-only memory (EEPROM), etc.

The memory system controller 115 can communicate with the memory devices 130 and 140 to perform operations such as reading data, writing data, or erasing data at the memory devices 130 and other such operations. The memory sub-system controller 115 can include hardware such as one or more integrated circuits and/or discrete components, a buffer memory, or a combination thereof. The memory system controller 115 can be a microcontroller, special purpose logic circuitry (e.g., a field programmable gate array (FPGA), an application specific integrated circuit (ASIC), etc.), or other suitable processing circuitry.

The controller 115 can include a processing device that can be one or more processors (e.g., processor 117) configured to execute instructions that can be stored in local memory 119. The local memory 119 can store instructions for various processes, operations, logic flows, and routines that control operation of the memory system 110, including handling communications between system 110 and host 102. In some examples, the memory 119 can store data structures such as tables used in association with performing error handling avoidance in accordance with various embodiments of the present disclosure.

In general, the controller 115 can receive commands or operations from the host 102 and can convert the commands or operations into instructions or appropriate commands to achieve the desired access to the memory devices 130 and 140. The controller 115 can be responsible for other operations such as wear leveling operations, garbage collection operations, error detection and error-correcting code (ECC) operations, encryption operations, caching operations, and address translations between a logical block address and a physical block address that are associated with the memory devices 130, 140.

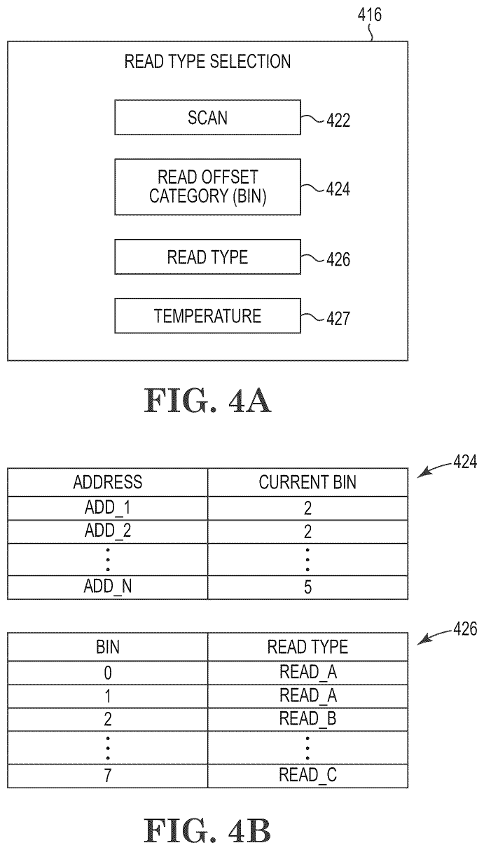

As illustrated in FIG. 1, the controller 115 includes a read management component 113 that can be used to implement error handling avoidance strategies in accordance with embodiments of the present disclosure. Although illustrated as being within the controller 115, at least a portion of the component 113 can be located external to controller 115. The read management component 113 can comprise hardware (e.g., circuitry), firmware, software, or a combination thereof. The read management component 113 includes an error handling component 114 that can implement various data recovery operations in response to host read operations that fail to be successfully decoded (e.g., via an ECC and/or LDPC engine), for example. The read management component 113 also includes a read type selection component 116. As described further herein, the read type selection component 116 can perform various operations designed to improve (e.g., reduce) the error handling trigger rate of system 110. For example, as described in association with FIGS. 4A and 4B, the read type selection component 116 can be configured to perform background scan operations in association with monitoring and/or tracking effects such as SCL that affect cell characteristics including, but not limited to, Vt shift (e.g., reduction) and read window budget loss. Such scan operations can be used, for example, to determine read offset categories (e.g., bins) of groups of cells (e.g., word lines, pages, word line groups, blocks, etc.). The component 116 can include data structures (e.g., look up tables) that can be used to determine a current bin corresponding to a target read address and to determine (e.g., select) one of multiple different read command types to use to read the data corresponding to the target read address. The component 116 can also utilize temperature data in association with determining the current read offset categories, for example. Such temperature data can include a current temperature at which data is being read and/or cross temperature data related to differences in temperature between when the data was programmed and read.

While the example memory system 110 in FIG. 1 has been illustrated as including the controller 115, in another embodiment of the present disclosure, a memory system 110 may not include a controller 115, and can instead rely upon external control (e.g., provided by a processor or controller separate from the memory system 110, such as by host 102 communicating directly with the memory devices 130, 140). Although the memory system 110 is shown as physically separate from the host 102, in a number of embodiments the memory system 110 can be embedded within the host 102. Alternatively, the memory system 110 can be removable from the host 102.

FIG. 2A illustrates example threshold voltage distributions associated with memory cells to be read in accordance with various embodiments of the present disclosure. FIG. 2B illustrates an example of the temporal threshold voltage shift that can be caused by slow charge loss (SCL) exhibited by memory cells that can be read in accordance with various embodiments of the present disclosure.

The Vt distributions 225-1, 225-2, 225-3, and 225-8, which can be referred to collectively as Vt distributions 225, represent states to which memory cells can be programmed. As an example, the Vt distributions 225 can correspond to a group of programmed cells of a particular page or block. In FIG. 2A, the read voltage 221-1 (Vread_1) corresponds to a read voltage centered at a valley between Vt distributions 225-2 and 225-3, which can be associated with a minimum BER in association with reading cells programmed to state 225-2 or 225-3.

FIG. 2B illustrates the Vt distributions 225 of FIG. 2A subsequent to a experiencing an amount of SCL time (e.g., time after programming). As described further herein, SCL can lead to a downward shift in Vt over time and/or widening of the Vt distributions 225, which leads to increased BER during reads. For example, utilizing the read voltage 221-1 to distinguish between the shifted states 225-2 and 225-3 shown in FIG. 2B results in a higher BER since the read voltage 221-1 is located within Vt distribution 225-3. As such, a portion of cells programmed to state 225-3 have a Vt less than read voltage 221-1 and will be read as being in state 225-2.

In FIG. 2B, read voltage 221-2 (Vread_2) represents a read voltage located at or near the valley between states 225-2 and 225-3. The read voltage 221-2 can be determined, for example, using a read type that includes valley tracking (e.g., a calibrated read). As noted herein, such a read type can lead to a reduced BER and/or trigger rate as compared to other read types, but does have a slower/longer associated read time, which reduces system performance.

In FIG. 2B, read voltage 221-3 (Vread_bin) represents a read voltage corresponding to a read type that utilizes particular sets of read offset voltages based on a number of predetermined read offset categories (e.g., “bins”). As described further below, the read offset categories can be determined based on different SCL time ranges, for example, which can be tracked via background scan operations. As shown in FIG. 2B, the read voltage 221-3 can provide a reduced BER as compared to read voltage 221-1 in association with reading the shifted states 225. However, the placement of read voltage 221-3 has an associated amount of read position loss (RPL) 228, which corresponds to a difference between the bin-based read voltage 221-3 and the valley-centered read voltage 221-2. Accordingly, the RPL associated with the bin-based read type that employs read voltage 221-3 leads to a higher BER as compared to a read type that employs read voltage 221-1 (determined via valley tracking, for example). However, in various instances, the BER associated with read voltage 221-3 can be sufficient to achieve a desired trigger rate (e.g., to maintain the BER below a threshold value) without having to employ a read type having a slower associated read time. As described further herein, various embodiments of the present disclosure involve tracking read offset categories (that can be based on SCL time and/or temperature), and determining which one of multiple different read types to execute to perform a read in order to achieve a target trigger rate while minimizing adverse effects to system performance (e.g., read time).

Although the example of FIGS. 2A and 2B illustrates cells programmable to one of 8-states (e.g., TLCs), embodiments are so limited. For example, the invention is applicable to MLCs, QLCs, etc.

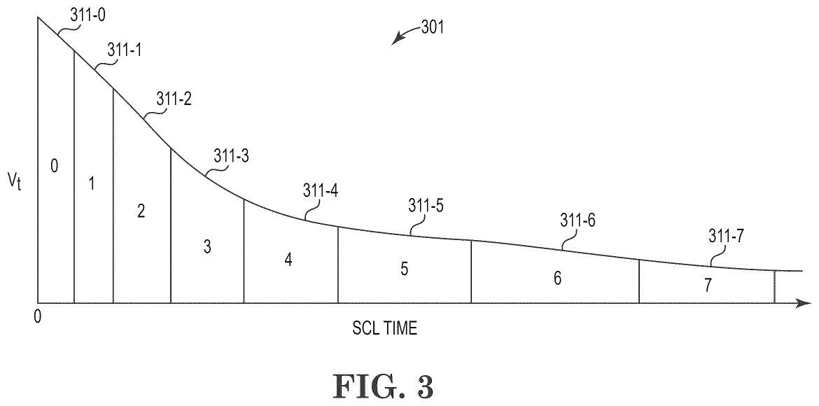

FIG. 3 depicts an example graph 301 illustrating the relationship between memory cell threshold voltage (Vt) and slow charge loss time as well as a number of read offset categories (e.g., “bins”) that can be used in association with error handling avoidance in accordance with various embodiments of the present disclosure. FIG. 3 illustrates seven read offset categories 311-0 to 311-7, which may be referred to collectively as read offset categories 311. The read offset categories 311 correspond to respective SCL time windows, with 311-0 corresponding to a time period immediately after programming and 311-7 corresponding to a much later time after programming, which could be measured in days, months, or years, for example.

The SCL times corresponding to respective groups of cells (e.g., pages, blocks, groups of word lines, etc.) can be tracked with the current mapping of groups to bins being stored in a data structure such as a lookup table (LUT), as described further in FIGS. 4A and 4B. Although SCL time can be tracked directly via timers within a memory system (e.g., system 110 shown in FIG. 1), the SCL time can also be tracked, for example, based on a determined amount of Vt shift, which can be used as a proxy for time based on the amount of Vt loss as shown in FIG. 3. For example, a scan operation can be performed (e.g., in the background) to determine by how much Vt levels of a particular data state (e.g., 225-8) have shifted downward, with the amount of shift indicating a particular SCL time and therefore corresponding bin 311. The scan operations used to determine the current bins 311 can be performed periodically (e.g., with a particular frequency) and the tables used to store corresponding mappings of addresses to bins 311 can be updated accordingly.

As described herein, the bins 311 can have respective sets of read offset voltages associated therewith. For example, the read offset voltages associated with groups of cells corresponding to bin 311-5 can be different (e.g., lower) than the read offset voltages associated with groups of cells corresponding to bin 311-2. For instance, the value of read offset voltage 221-3 (Vread_bin) shown in FIG. 2B is variable and depends on the current bin to which the address being read corresponds, which depends on SCL time.

FIG. 4A illustrates an example read type selection component 416 associated with error handling avoidance in accordance with various embodiments of the present disclosure. The read type selection component 416 can be analogous to the component 116 described in FIG. 1. In various embodiments, the read type selection component 416 is configured to track respective read offset categories (bins) corresponding to groups of memory cells within an array (e.g., on a page basis, block basis, word line group basis, etc.), such as described in FIG. 3. The bins can have different associated sets of read voltages and can be based on SCL time after programming and/or cross temperature data, for example. The read type selection component 416 includes a scan component 422 that can be configured to periodically perform a background scan to determine (e.g., update) the current read offset categorizations for the programmed groups of cells.

As shown in FIG. 4A, the read type selection component 416 includes a table 424 that can provide mappings of read addresses to a current bin and a table 426 that provides mappings of read offset categorizations to different read types. FIG. 4B illustrates specific examples of tables 424 and 426. The address field of table 424 can correspond to a physical address targeted for a host read operation. In FIG. 4B, address ADD_1 and ADD_2 both correspond to a current bin 2 (and its corresponding read offset voltages), and address ADD_N corresponds to a current bin 5. In a number of embodiments, the read type selection component 416 includes a temperature sensor 427 (or temperature data from a temperature sensor) that can be used to determine the current bin to which a particular address corresponds. For instance, colder read temperatures can be associated with bins corresponding to longer SCL times since colder read temperatures can result in increased Vt shifts, lower read margins, and higher BERs.

Example table 426 shown in FIG. 4B illustrates different read types (e.g., READ_A, READ_B, READ_C) corresponding to the bins 0 to 7. As an example, read type READ_A can correspond to a read operation having a fastest associated read time, read type READ_C can correspond to read operation having a slowest associated read time, and read type READ_B can correspond to a read operation having an associated read time between that of READ_A and READ_C. As an example, READ_C can be a read type that implements valley tracking to determine the read voltage offsets, READ_B can be a read type that utilizes default sets of read offset voltages having some associated read position loss, and READ_A can be a read type that is similar to READ_B but has a faster read time due to a shortened precharge time, for example. Embodiments are not limited to these particular read types; however, in general, the different read types have different respective associated BERs and read times, allowing the system to select a read type (e.g., issue a selected read command) that achieves an acceptable/target trigger rate without unduly reducing system performance due to increased read time. The different read types can be implemented via separate read commands or set features, for example.

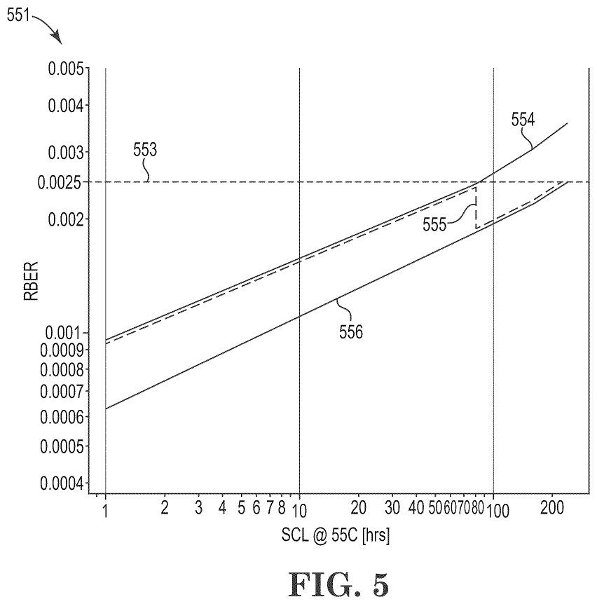

FIG. 5 is a graph 551 illustrating BER over time associated with a number of read types that can be performed in association with error handling avoidance in accordance with various embodiments of the present disclosure. In FIG. 5, line 553 represents a threshold BER above which error handling can be invoked/triggered. Curve 554 represents BER over SCL time associated with a first type of read operation, curve 556 represents BER over SCL time associated with a second type of read operation, and curve 555 represents BER over SCL time associated with a hybrid approach in accordance with embodiments of the present disclosure.

As an example, read operation type 556 can be a read operation that utilizes valley tracking (e.g., auto read calibration) and which is associated with low BER but relatively high read latency. Read operation type 554 can be a read operation type that provides adjusted read offset voltages according to “bins” corresponding to different SCL times as described in association with FIG. 3, for example. Accordingly, read operation type 554 can provide an improved BER as compared to default read offsets, but still has residual read position loss (RPL) associated therewith.

As illustrated in FIG. 5, the read type corresponding to curve 554 reaches the threshold BER before the read type corresponding to curve 556. Therefore, as illustrated by curve 555, embodiments of the present disclosure can involve selecting the read operation type 554 for low SCL times in which the corresponding BER is below the threshold 553, and then switching to selecting the read operation type 556 when the SCL time reaches or nears an amount at which the BER reaches or nears the threshold 553. In this manner, the read management component of the system (e.g., read management component 113 of system 110) can take advantage of the improved (e.g., faster) read performance associated with read operation type 554 (as compared to read operation type 556) for lower SCL times and then achieve an improved trigger rate for higher SCL times by switching to the more accurate (and slower) read operation type 556.

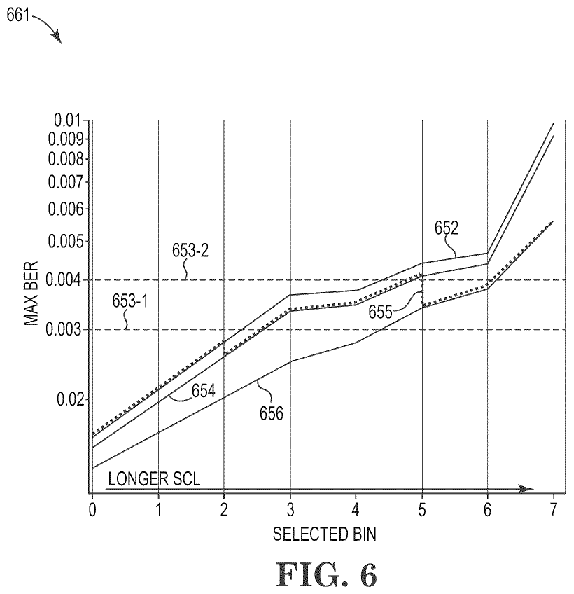

FIG. 6 is a graph 661 illustrating BER over time (e.g., SCL time) for multiple different read types that are selectable, based on a determined current read offset category (e.g., bin), to perform a read operation in association with error handling avoidance in accordance with various embodiments of the present disclosure. In FIG. 6, line 653-1 represents a first threshold BER above which error handling can be invoked/triggered and line 653-1 represents a second threshold BER rate above which error handling can be invoked/triggered. Curve 654 represents BER over SCL time associated with a first type of read operation, curve 656 represents BER over SCL time associated with a second type of read operation, curve 652 represents BER over SCL time associated with a third type of read operation, and curve 655 represents BER over SCL time associated with a hybrid approach in accordance with embodiments of the present disclosure.

As an example, read operation type 656 can be a read operation that utilizes valley tracking (e.g., auto read calibration) and which is associated with low BER but relatively high read latency. Read operation type 654 can be a read operation type that provides adjusted read offset voltages according to “bins” corresponding to different SCL times as described in association with FIG. 3, for example. Accordingly, read operation type 654 can provide an improved BER as compared to default read offsets, but still has residual read position loss (RPL) associated therewith. Read operation type 652 can be the same as read operation type 654 but with a reduced associated precharge time which results in faster read time and higher BER as illustrated.

The bins 0 to 7 shown in FIG. 6 represent read offset categories, which can be determined (e.g., tracked) as described herein above. Curve 655 illustrates a manner in which embodiments of the present disclosure involve selecting one of multiple read types (e.g., 652, 654, or 656) based on the determined read offset category (e.g., bin) corresponding to the location (e.g., address) being read, with the read offset categories correlating to SCL time and/or temperature.

As illustrated by curve 655, in the example shown in FIG. 6, the read type corresponding to curve 652 (e.g., the fastest read type) is selected for bins 0-1, the read type corresponding to curve 654 is selected for bins 2-4, and the read type corresponding to curve 656 (e.g., the slowest read type) is selected for bins 5-7.

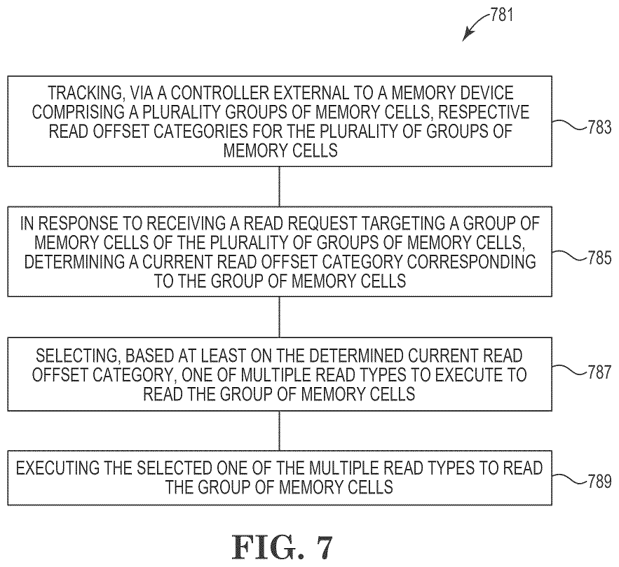

FIG. 7 is a flow diagram 781 that illustrates an example method for error handling avoidance in accordance with various embodiments of the present disclosure. The method 781 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 781 is performed by the controller 115 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At step 783, the method includes tracking, via a controller external to a memory device (e.g., controller 115) comprising a plurality groups of memory cells, respective read offset categories for the plurality of groups of memory cells. The read offset categories can be referred to as bins and can have different respective sets of read offset voltages associated therewith. In various embodiments, the bins can be associated with different respective ranges of SCL time and/or temperature data.

At step 785, the method includes, in response to receiving a read request targeting a group of memory cells of the plurality of groups of memory cells, determining a current read offset category corresponding to the group of memory cells. As an example, the current read offset categories corresponding to respective groups of cells (e.g., pages, blocks, word line groups, etc.) can be stored in (and can be determined from) a lookup table such as table 424 described in FIGS. 4A and 4B.

At step 787, the method includes selecting, based at least on the determined current read offset category, one of multiple read types to execute to read the group of memory cells. As an example, mappings of read offset categories to read types can be stored in a lookup table such as table 426 described in FIGS. 4A and 4B. The different read types can have different associated BERs and read latencies as described herein. In various embodiments, the quantity of different read types is at least two. The particular read type selected can be designed to achieve a target trigger rate while maximizing read/system performance. At step 789, the method includes executing the selected one of the multiple read types to read the group of memory cells.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, which manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, which can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

The figures herein follow a numbering convention in which the first digit or digits correspond to the drawing figure number and the remaining digits identify an element or component in the drawing. Similar elements or components between different figures may be identified by the use of similar digits. For example, 116 may reference element “16” in FIG. 1, and a similar element may be referenced as 416 in FIG. 4A. As will be appreciated, elements shown in the various embodiments herein can be added, exchanged, and/or eliminated so as to provide a number of additional embodiments of the present disclosure.

For the purposes of the present disclosure, the phrase “A and/or B” means (A), (B), (A) or (B), or (A and B). For the purposes of the present disclosure, the phrase “A, B, and/or C” means (A), (B), (C), (A and B), (A and C), (B and C), or (A, B and C). Additionally, the phrase “at least one of A and B” means one or more of (A) or one or more of (B), or one or more of (A) and one or more of (B) such that both one or more of (A) and one or more of (B) is not required.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus, comprising:
a number of memory components; and
a controller coupled to the number of memory components and comprising a read management component configured to:
track respective read offset categories for a plurality of groups of memory cells;
in response to receiving a read request targeting a group of memory cells of the plurality of groups of memory cells:
determine a current read offset category corresponding to the group of memory cells; and
select, based at least on the determined current read offset category, one of multiple read types to execute to read the group of memory cells; and
read the group of memory cells using the selected one of the multiple read types.

2. The apparatus of claim 1, wherein the read management component is configured to track the respective read offset categories by periodically performing a background scan to determine respective amounts of slow charge loss (SCL) associated with the plurality of group of memory cells.

3. The apparatus of claim 1, wherein the read offset categories are associated with different respective sets of read trim offsets.

4. The apparatus of claim 1, wherein the read offset categories correspond to different respective amounts of time since the groups of cells were programmed.

5. The apparatus of claim 1, wherein the multiple read types comprise:
a first read type corresponding to a fastest read time among the multiple read types;
a second read type corresponding to a slowest read time among the multiple read types; and
a third read type corresponding to a read time between the fastest read time and the slowest read time.

6. The apparatus of claim 5, wherein the read management component is configured to:
select the first read type responsive to the determining that the current read offset category is one of a first subset of the read offset categories;
select the second read type responsive to determining that the current read offset category is one of a second subset of the read offset categories; and
select the third read type responsive to determining that the current read offset category is one of a third subset of the read offset categories.

7. The apparatus of claim 5, wherein the second read type is associated with a reduced amount of read position loss (RPL) as compared to the third read type.

8. The apparatus of claim 7, wherein the second read type is associated with a calibrated read operation.

9. The apparatus of claim 1, wherein the multiple read types are associated with different read commands or set features.

10. A method, comprising:
tracking, via a controller external to a memory device comprising a plurality groups of memory cells, respective read offset categories for the plurality of groups of memory cells;
in response to receiving a read request targeting a group of memory cells of the plurality of groups of memory cells, determining a current read offset category corresponding to the group of memory cells;
selecting, based at least on the determined current read offset category, one of multiple read types to execute to read the group of memory cells; and
executing the selected one of the multiple read types to read the group of memory cells.

11. The method of claim 10, wherein the method includes determining a temperature of the memory device in association with determining the current read offset category.

12. The method of claim 10, wherein tracking the respective read offset categories includes performing, via the controller, a background scan operation.

13. The method of claim 10, wherein the respective read offset categories correspond to respective different ranges of slow charge loss (SCL) time.

14. The method of claim 10, wherein the respective read offset categories each have different respective read voltage offsets associated therewith.

15. The method of claim 10, wherein the multiple read types include a first read type associated with a valley tracking operation.

16. The method of claim 15, wherein the multiple read types include a second read type that does not involve a valley tracking operation.

17. The method of claim 16, wherein the multiple read types include a third read type that is the same as the second read type but for a shorter associated precharge time.

18. An apparatus, comprising:
a number of memory devices; and
a controller coupled to the number of memory devices and configured to:
track respective read offset categories for a plurality of groups of memory cells;
in response to receiving a read request targeting a group of memory cells of the plurality of groups of memory cells:
determine, via a first lookup table, a current read offset category corresponding to the group of memory cells; and
select, based at least on the determined current read offset category, one of multiple read types to execute to read the group of memory cells; and
read the group of memory cells using the selected one of the multiple read types.

19. The apparatus of claim 18, wherein the controller is configured to select the one of multiple read types from a second lookup table.

20. The apparatus of claim 18, wherein the read offset categories correspond to different respective slow charge loss (SCL) time windows.
